(19) United States
(12) Patent Application Publication
(10) Pub. No.: US 2025/0006778 A1
(43) Pub. Date: Jan. 2, 2025

(54) CAPACITOR AND SEMICONDUCTOR DEVICE INCLUDING THE SAME

(71) Applicant: Samsung Electronics Co., Ltd., Suwon-si (KR)

(72) Inventors: Haeryong KIM, Suwon-si (KR); Eunae CHO, Hwaseong-si (KR); Beomseok KIM, Hwaseong-si (KR); Jeeeun YANG, Suwon-si (KR); Jooho LEE, Suwon-si (KR)

(73) Assignee: Samsung Electronics Co., Ltd., Suwon-si (KR)

(21) Appl. No.: 18/510,973

(22) Filed: Nov. 16, 2023

(30) Foreign Application Priority Data
Jun. 30, 2023 (KR) 10-2023-0085337

(51) Int. Cl. H01G 4/08; H01G 4/008; H10B 12/00

(52) U.S. Cl. CPC H01L 28/56; H01G 4/008; H01G 4/085; H01L 28/60; H01L 28/65; H10B 12/31; H01G 4/1209; H01G 4/1218; H01G 4/1236

(57) ABSTRACT

A capacitor includes a first electrode, a second electrode spaced apart from the first electrode, a dielectric layer arranged between the first electrode and the second electrode, and an interface layer arranged between the second electrode and the dielectric layer, wherein the interface layer includes a first element, a second element, and a third element, the first element includes aluminum (Al), the second element includes gallium (Ga), and the third element includes oxygen (O).

### CROSS-REFERENCE TO RELATED APPLICATION

This application is based on and claims priority under 35 U.S.C. § 119 to Korean Patent Application No. 10-2023-0085337, filed on Jun. 30, 2023, in the Korean Intellectual Property Office, the disclosure of which is incorporated by reference herein in its entirety.

### BACKGROUND

### 1. Field

The disclosure relates to a capacitor and a semiconductor device including the same.

### 2. Description of the Related Art

Semiconductor devices, such as memories and transistors, are used in various household and industrial devices. Higher performance in household and industrial devices is leading to higher integration and miniaturization of the semiconductor devices.

According to the higher integration and miniaturization of the semiconductor devices, the sizes of the semiconductor devices have been reduced. The capacity of a capacitor is decreased and a leakage current is increased according to a decrease in the size of the capacitor, and thus, various methods are proposed to solve such issues.

For example, a method of changing a structure of the capacitor, such as increasing the electrode area of the capacitor or adding an interface layer for suppressing the leakage current, has been proposed.

### SUMMARY

Provided is a capacitor with high capacitance and a low leakage current.

Provided is a semiconductor device including a capacitor with high capacitance and a low leakage current.

Additional aspects will be set forth in part in the description which follows and, in part, will be apparent from the description, or may be learned by practice of the presented embodiments of the disclosure.

According to an aspect of the disclosure, a capacitor includes a first electrode, a second electrode spaced apart from the first electrode, a dielectric layer electrically insulating the first electrode from the second electrode, and an interface layer between the second electrode and the dielectric layer, wherein the interface layer includes a first element, a second element, and a third element, the first element includes aluminum (Al), the second element includes gallium (Ga), and the third element includes oxygen (O).

The interface layer may include a plurality of layers, and the plurality of layers may include at least one first layer including an aluminum oxide and at least one second layer including a gallium oxide.

The interface layer may be amorphous.

The interface layer may be in direct contact with the second electrode, and the interface layer may be in direct contact with the dielectric layer.

The first electrode may include at least one of titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb), an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, or an oxide of Nb, a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb, or a combination thereof.

The interface layer may be a first interface layer and the capacitor may further include a second interface layer between the dielectric layer and the first electrode.

The second interface layer may include an oxide of a material included in the first electrode.

The second electrode may include a same material as the first electrode.

The dielectric layer may include at least one of zirconium oxide (ZrO₂), hafnium oxide (HfO₂), titanium oxide (TiO₂), aluminum oxide (Al₂O₃), or a combination thereof.

The dielectric layer may include an oxide having a perovskite type crystal structure.

The dielectric layer may include at least one of strontium (Sr), barium (Ba), titanium (Ti), hafnium (Hf), yttrium (Y), or a combination thereof and oxygen (O).

A thickness of the interface layer may be 15 Å or less.

A thickness of the dielectric layer may be 100 Å or less.

According to another aspect of the disclosure, a semiconductor device includes a transistor including a semiconductor substrate, the semiconductor substrate including a source region, a drain region, a channel region between the source region and the drain region, and a gate stack over the channel region, and a capacitor electrically connected to the transistor, wherein the capacitor includes a first electrode, a second electrode spaced apart from the first electrode, a dielectric layer electrically insulating the first electrode from the second electrode, and an interface layer arranged between the second electrode and the dielectric layer, wherein the interface layer includes a first element, a second element, and a third element, the first element includes aluminum (Al), the second element includes gallium (Ga), and the third element includes oxygen (O).

The interface layer may include a plurality of layers, and the plurality of layers may include at least one first layer including an aluminum oxide and at least one second layer including a gallium oxide.

The interface layer may be amorphous.

The interface layer may be in direct contact with the second electrode, and the interface layer may be in direct contact with the dielectric layer.

The first electrode may include at least one of titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb), an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, or an oxide of Nb, a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb, or a combination thereof.

The interface layer may be a first interface layer and the capacitor may further include a second interface layer arranged between the dielectric layer and the first electrode.

The dielectric layer may include at least one of zirconium oxide (ZrO₂), hafnium oxide (HfO₂), titanium oxide (TiO₂), aluminum oxide (Al₂O₃), or a combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a capacitor according to at least one embodiment;

FIG. 2 is a graph showing capacitance with respect to a voltage of a capacitor, according to at least one embodiment;

FIG. 3 is a graph showing a leakage current according to an equivalent oxide layer thickness of a capacitor, according to at least one embodiment;

FIG. 4 is a cross-sectional view of a capacitor according to at least one embodiment;

FIG. 5 is a cross-sectional view of a capacitor according to at least one embodiment;

FIGS. 6A and 6B are diagrams showing a valence band offset (VBO) of a capacitor;

FIGS. 7A and 7B are diagrams for describing structural stability according to a configuration of an interface layer;

FIGS. 8A and 8B are diagrams showing element distributions of capacitors;

FIG. 9 is a transmission electron microscope (TEM) image of a cross-section of a capacitor, according to at least one embodiment;

FIG. 10 illustrates an X-ray diffraction (XRD) spectrum showing crystallization of a capacitor, according to at least one embodiment;

FIG. 11 is a circuit diagram for describing a schematic circuit configuration of a semiconductor device employing a capacitor according to some embodiments;

FIG. 12 is a diagram showing a semiconductor device according to at least one embodiment;

FIG. 13 is a diagram showing a semiconductor device according to at least one embodiment; and

FIGS. 14 and 15 are conceptual diagrams schematically showing device architectures applicable to a semiconductor device, according to some embodiments.

### DETAILED DESCRIPTION

Hereinafter, a capacitor and a semiconductor device including the same, according to various embodiments, will be described in detail with reference to accompanying drawings. In the drawings, like reference numerals denote like elements and the sizes of the elements may be exaggerated for clarity and convenience of description. Also, embodiments described below are only examples and various modifications may be made from such embodiments.

As used herein, the term “and/or” includes any and all combinations of one or more of the associated listed items. Expressions such as “at least one of,” when preceding a list of elements, modify the entire list of elements and do not modify the individual elements of the list. Additionally, when the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

When an element is described to be “on” or “above” another element, the element may contact and be directly on the other element or may be on the other element without contacting the other element. Additionally, spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, device may be otherwise oriented, for example, rotated 90 degrees or at other orientations, and the spatially relative descriptors used herein should be interpreted accordingly. An expression used in the singular encompasses the expression in the plural, unless it has a clearly different meaning in the context. In addition, when a part “comprises (includes)” a certain element, the part may further include another element instead of excluding the other element, unless otherwise stated.

The use of the term “the” and similar indicative terms may correspond to both the singular and the plural. Operations constituting a method may be performed in an appropriate order and are not necessarily limited by a state order unless otherwise stated or an order is clearly stated.

Connection or connection members of lines between components shown in the drawings exemplarily represent functional connections and/or physical or circuit connections, and in an actual apparatus, may be replaced or may be implemented as various additional functional connections, physical connections, or circuit connections. In addition, as used herein, functional blocks, including those described with terms such “ . . . unit”, etc., denote units that are configured to perform at least one function or operation, which may be implemented as processing circuitry such as hardware, software, and/or a combination thereof. For example, the processing circuitry more specifically may include (and/or be included in), but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The use of all examples or exemplary terms is merely for describing the technical ideas in detail, and the scope of the disclosure is not limited by the examples or exemplary terms unless limited by the claims.

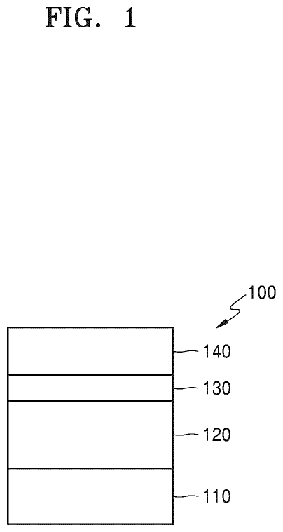

FIG. 1 is a cross-sectional view of a schematic structure of a capacitor 100, according to at least one embodiment.

Referring to FIG. 1, the capacitor 100 includes a first electrode 110, a second electrode 140 spaced apart from the first electrode 110, a dielectric layer 120 arranged between the first electrode 110 and the second electrode 140, and an interface layer 130 arranged between the second electrode 140 and the dielectric layer 120.

The first electrode 110 may include a conductor, such as at least one of a metal, a metal nitride, a metal oxide, and/or a combination thereof. For example, the first electrode 110 may include a metal, such as titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), and/or niobium (Nb); and/or a conductive metal oxide, such as a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb, and/or an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, and/or an oxide of Nb. A thickness of the first electrode 110 may be, for example, about 10 Å to about 100 Å. The thickness of the first electrode 110 may be, for example, about 20 Å to about 50 Å.

The dielectric layer 120 may include an oxide having a perovskite type crystal structure. For example, dielectric layer 120 may include at least one of strontium (Sr), barium (Ba), titanium (Ti), hafnium (Hf), and/or yttrium (Y), and oxygen (O). For example, the dielectric layer 120 may be an oxide of at least one of Sr, Ba, Ti, Hf, and/or Y. The dielectric layer 120 may include, for example, BaSrTiO₃. However, at least one embodiment is not limited thereto, and the dielectric layer 120 may include a metal oxide. The dielectric layer 120 may include a metal oxide including, for example, zirconium oxide (ZrO₂), hafnium oxide (HfO₂), titanium oxide (TiO₂), aluminum oxide (Al₂O₃), and/or a combination thereof.

The dielectric layer 120 may have, for example, one or more structures selected from a plate structure, a trench structure, and a pillar structure, but is not limited thereto and any structure used in the related field may be used. In view of the dielectric layer 120 having such a structure, the dielectric layer 120 may be applied to various types of devices. The dielectric layer 120 may have, for example, a single-layer structure or a multi-layer structure. The multi-layer structure may be a two-layer structure, a three-layer structure, or a four-layer structure, but is not limited thereto, and the multi-layer structure may include more layers depending on a desired performance.

The dielectric layer 120 may be an epitaxial layer. The dielectric layer 120 may be formed through epitaxial growth. Accordingly, the dielectric layer 120 may have the same or similar crystal structure and the same or similar lattice constant as a thin-film electrode layer (e.g., first electrode 110), and interface stability may be increased. A part or all of the dielectric layer 120 may include an epitaxial region.

A thickness of the dielectric layer 120 may be, for example, about 10 Å to about 100 Å. The thickness of the dielectric layer 120 may be, for example, about 20 Å to about 50 Å. When the thickness of the dielectric layer 120 is too small, capacity of a capacitor per unit volume may be low, and when the thickness of the dielectric layer 120 is too large, it may be difficult for a capacitor to satisfy the volume required in a memory device.

The interface layer 130 may include a first element, a second element, and a third element. The first element may include aluminum (Al), the second element may include gallium (Ga), and the third element may include oxygen (O). The interface layer 130 may include aluminum gallium oxide. For example, in at least one embodiment, the interface layer 130 may include a compound represented by Chemical Formula 1 below.

### Chemical Formula 1

AlₓGa_{y}O_{z}

Here, x is a real number of more than 0 to less than 2, y is a real number of more than 0 to less than 2, and z is 3.

The interface layer 130 may be amorphous. However, at least one embodiment is not limited thereto, and the interface layer 130 may be crystalline. The interface layer 130 may be in direct contact with the second electrode 140. The second electrode 140 in direct contact with the interface layer 130 may be an upper electrode as illustrated. Here, the upper electrode indicates that it is manufactured after the first electrode 110, based on manufacturing processes. The interface layer 130 may be in direct contact with the dielectric layer 120. The thickness of the interface layer 130 may be 15 Å or less.

The capacitor 100 includes the interface layer 130, and thus, capacitance may be increased and leakage current density may be decreased. This will be described in detail below.

The second electrode 140 may include the same or similar material as the first electrode 110. For example, the second electrode 140 may include a conductor, such as a metal, a metal nitride, a metal oxide, or a combination thereof. For example, the second electrode 140 may include a metal, such as Ti, Ni, Al, Ta, W, Pt, Pd, Au, Ir, Rh, Mo, V, and/or Nb; and/or a conductive metal oxide, such as a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb, and/or an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, and/or an oxide of Nb. The thickness of the second electrode 140 may be, for example, about 10 Å to about 100 Å. The thickness of the second electrode 140 may be, for example, about 20 Å to about 50 Å.

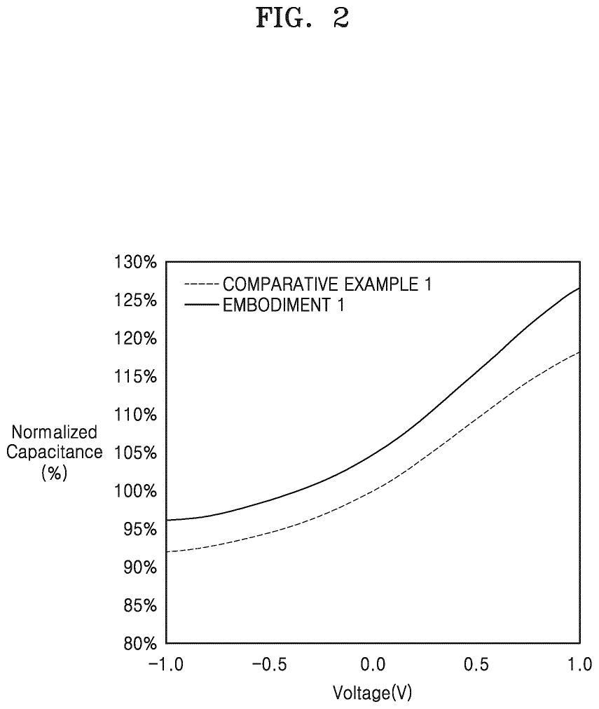

FIG. 2 is a graph showing capacitance with respect to a voltage of a capacitor, according to at least one embodiment.

### Embodiment 1

TiN was prepared as a first electrode. A ZrO₂ dielectric layer was formed on the first electrode, and an interface layer was formed by growing an AlₓGa_{y}O_{z} thin film on the dielectric layer by using atomic layer deposition (ALD). Then, a capacitor of Embodiment 1 was manufactured by forming a TiN second electrode on the interface layer.

### Comparative Example 1

A capacitor of Comparative Example 1 was manufactured in a same manner as Embodiment 1, except that AlOₓ was used instead of AlₓGa_{y}O_{z} while forming an interface layer.

Capacitance was measured for the capacitors manufactured in Embodiment 1 and Comparative Example 1, and results thereof are shown in FIG. 2. Keithley 4200 A Analyzer was used as a measurement device and the capacitance was measured according to a voltage change (from −1 V to 1 V).

Referring to FIG. 2, the capacitor of Embodiment 1 shows about 5% higher capacitance than the capacitor of Comparative Example 1. Compared with the capacitor of Comparative Example 1, the capacitor of Embodiment 1 displays excellent capacitance characteristics.

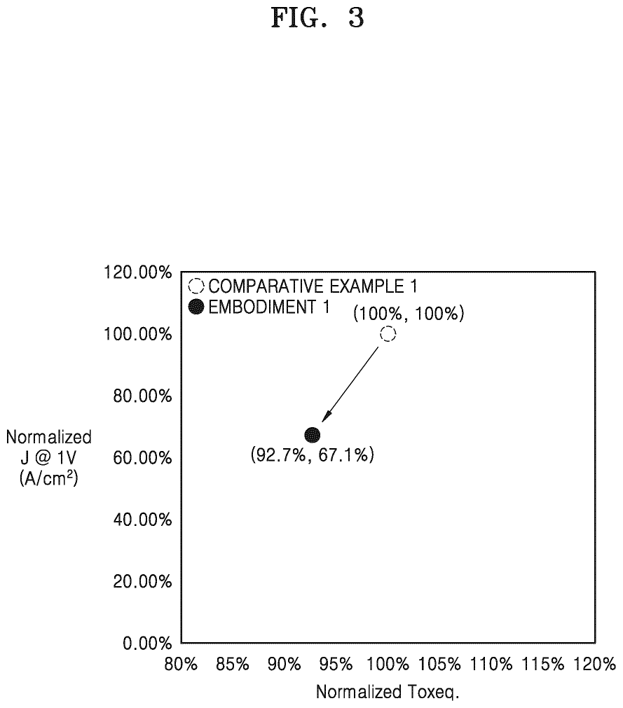

FIG. 3 is a graph showing a leakage current according to an equivalent oxide layer thickness of a capacitor, according to at least one embodiment.

A leakage current according to an equivalent oxide layer thickness (T_{oxeq}) was measured for the capacitors manufactured in Embodiment 1 and Comparative Example 1, and results thereof are shown in FIG. 3. Keithley 4200 A Analyzer was used as a measurement device, and the leakage current is current density when a voltage of 1 V is applied to the capacitor. The thickness of a dielectric layer is indicated as the equivalent oxide layer thickness.

Referring to FIG. 3, compared with the capacitor of Comparative Embodiment 1, the capacitor of Example 1 displays about 7.3% lower equivalent oxide layer thickness and about 32.9% lower leakage current density. Compared with the capacitor of Comparative Example 1, the capacitor of Embodiment 1 displays a relatively low equivalent oxide layer thickness, i.e., a high dielectric constant, and low leakage current characteristics together.

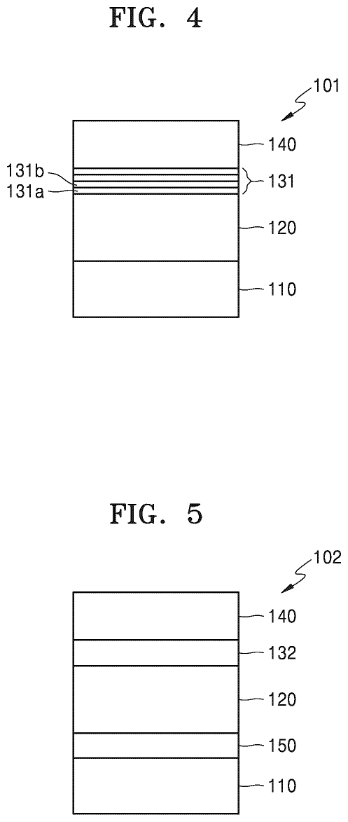

FIG. 4 is a cross-sectional view of a capacitor 101 according to at least one embodiment.

Referring to FIG. 4, the capacitor 101 includes the first electrode 110, the second electrode 140 spaced apart from the first electrode 110, the dielectric layer 120 arranged between the first electrode 110 and the second electrode 140, and an interface layer 131 arranged between the second electrode 140 and the dielectric layer 120. The first electrode 110, the dielectric layer 120, and the second electrode 140 may be the same as the first electrode 110, the dielectric layer 120, and the second electrode 140 of the capacitor 100 of FIG. 1, therefore descriptions overlapping those of FIG. 1 will not be provided again.

The interface layer 131 may include a plurality of layers. In FIG. 4, the interface layer 131 is illustrated as including four layers, but the embodiments are not limited thereto and the interface layer 131 may include, e.g., two or more layers. The plurality of layers may include at least one first layer 131a including an aluminum oxide and at least one second layer 131b including gallium oxide.

Each of the plurality of layers, i.e., the at least one first layer 131a and the at least one second layer 131b, included in the interface layer 131 may each include a compound represented by Chemical Formula 1 described above with reference to FIG. 1. Composition ratios of aluminum and gallium of the compounds represented by Chemical Formula 1 included in the at least one first layer 131a and the at least one second layer 131b may be different from each other.

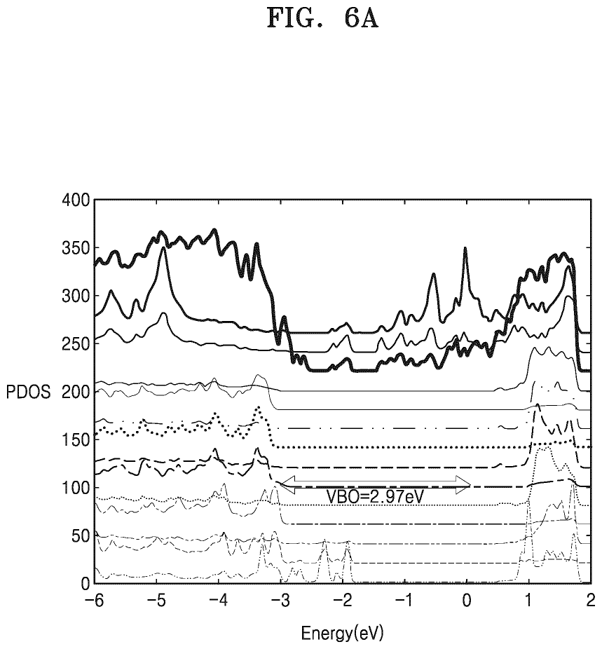

FIG. 5 is a cross-sectional view of a capacitor 102 according to at least one embodiment.

Referring to FIG. 5, the capacitor 102 includes the first electrode 110, the second electrode 140 spaced apart from the first electrode 110, the dielectric layer 120 arranged between the first electrode 110 and the second electrode 140, an interface layer 132 arranged between the second electrode 140 and the dielectric layer 120, and a second interface layer 150 arranged between the dielectric layer 120 and the first electrode 110. The interface layer 132 may also be referred to as a first interface layer 132 to be distinguished from the second interface layer 150. The first electrode 110, the dielectric layer 120, and the second electrode 140 may be the same as the first electrode 110, the dielectric layer 120, and the second electrode 140 of the capacitor 100 of FIG. 1. The interface layer 132 may be the interface layer 130 described with reference to FIG. 1 or the interface layer 132 described with reference to FIG. 4, therefore descriptions overlapping those of FIG. 1 will not be provided again.

The second interface layer 150 may include an oxide of a material included in the first electrode 110. For example, when the first electrode 110 is TiN, the second interface layer 150 may be TiON. The second interface layer 150 may be formed while the dielectric layer 120 is formed on the first electrode 110. For example, when the first electrode 110 is TiN, a TiON layer may be formed between the first electrode 110 and the dielectric layer 120 while the dielectric layer 120 is formed on a TiN electrode. The thickness of the second interface layer 150 may be, for example, about 5 Å to about 20 Å. The thickness of the second interface layer 150 may be, for example, about 5 Å to about 10 Å.

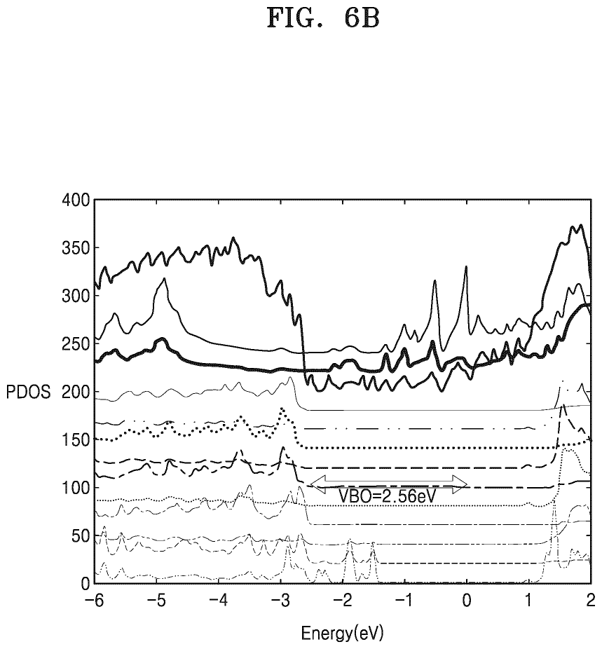

FIGS. 6A and 6B are diagrams showing a valence band offset (VBO) of a capacitor.

FIG. 6A illustrates VBO model data of Comparative Example 1 and FIG. 6B illustrates VBO modeling data of Example 1.

Referring to FIGS. 6A and 6B, the capacitor of Comparative Example 1 displays VBO of about 2.97 eV, and the capacitor of Example 1 displays VBO of about 2.56 eV. By using an aluminum gallium oxide for an interface layer, it is determined that a VBO of a capacitor is decreased by about 0.4 eV while a conduction band offset (CBO) thereof is increased by about 0.4 eV. Compared with the capacitor of Comparative Example 1, the capacitor of Embodiment 1 has about 0.4 eV greater CBO and thus may display enhanced leakage current characteristics.

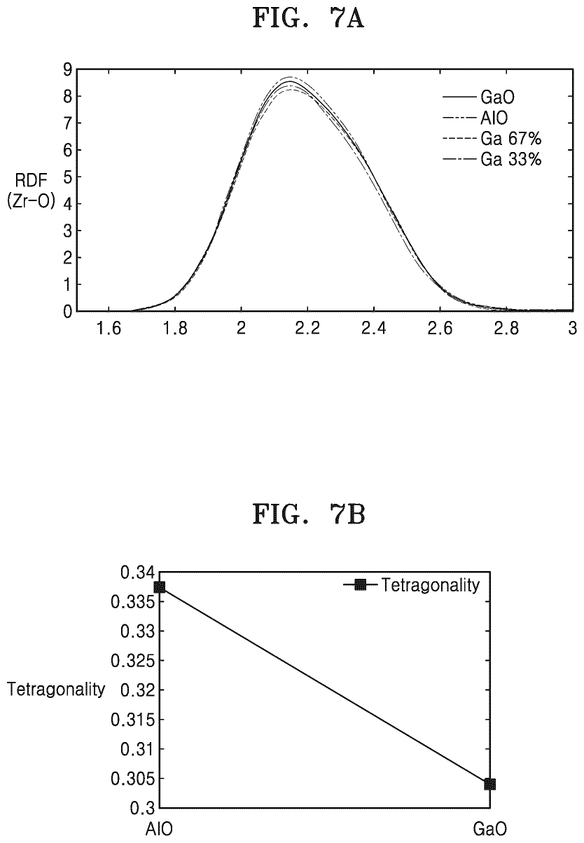

FIGS. 7A and 7B are diagrams for describing structural stability according to a configuration of an interface layer.

Referring to FIG. 7A, when only an aluminum oxide is included in an interface layer, a peak is not separated, but when an aluminum oxide and a gallium oxide are mixed in an interface layer and when only a gallium oxide is included in an interface layer, peaks tend to separate. Accordingly, it may be determined that an interface layer has a tetragonal phase when the interface layer includes a gallium oxide. Based on an interface layer having a tetragonal phase, it may be determined that a high dielectric constant is exhibited when the interface layer has a gallium oxide.

Referring to FIG. 7B, a tetragonality index has a value of about 0.337 when only an aluminum oxide is included in an interface layer, and a tetragonality index has a value of about 0.303 when only a gallium oxide is included in an interface layer. A tetragonal phase structure is stabilized when a tetragonality index is close to 0.

Referring to FIGS. 7A and 7B, it is determined that an interface layer has a stable tetragonal phase structure and a high dielectric constant by including a gallium oxide.

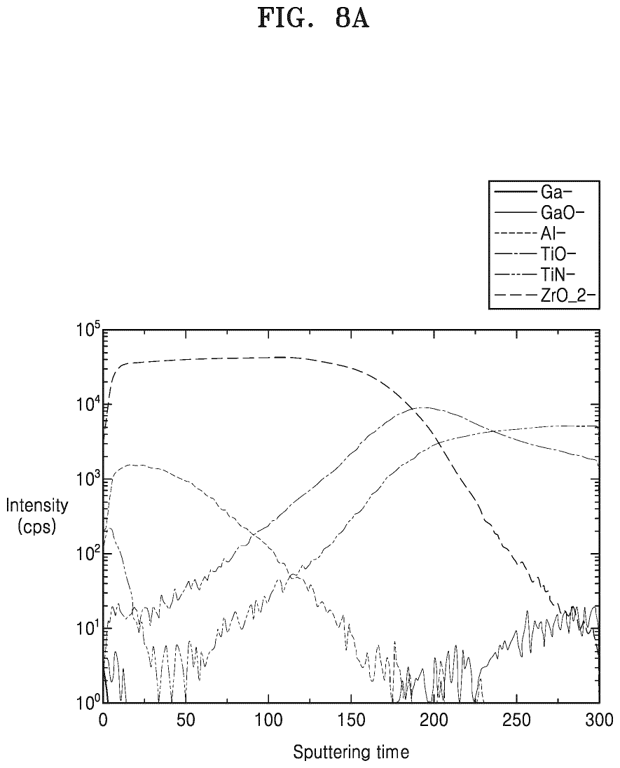

FIGS. 8A and 8B are diagrams showing element distributions of the capacitors of Comparative Example 1 and Embodiment 1, respectively.

FIG. 8A illustrates time of flight (TOF) secondary ion mass spectrometry (SIMS) data showing the element distribution of Comparative Example 1 and FIG. 8B illustrates TOF SIMS data showing the element distribution of Embodiment 1.

Referring to FIGS. 8A and 8B, it is determined that aluminum and gallium oxides are not found in a same sputtering time for the capacitor of Comparative Example 1, whereas aluminum and gallium oxides are found in the same sputtering time for the capacitor of Embodiment 1. Accordingly, it is determined that the aluminum oxide and the gallium oxide are not present at a same location for the capacitor of Comparative Example 1 whereas the aluminum oxide and the gallium oxide are present at a same location for the capacitor of Embodiment 1.

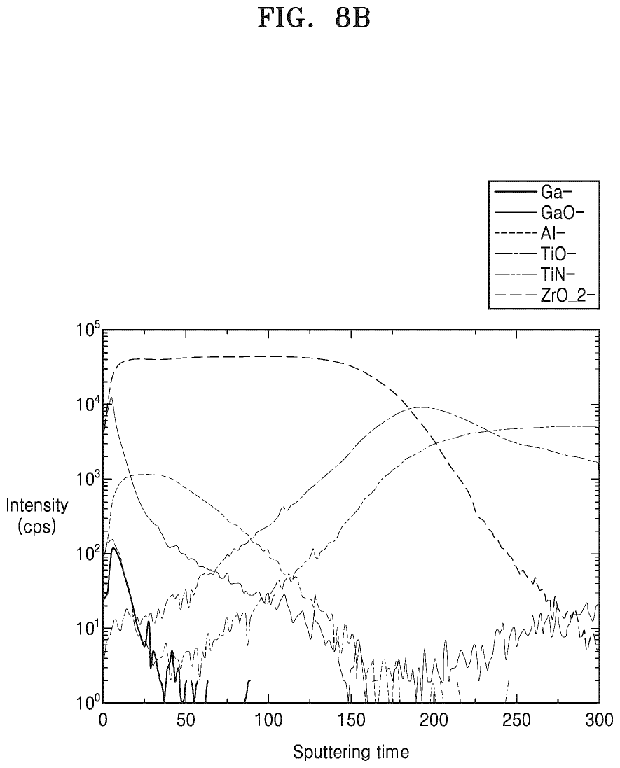

FIG. 9 is a transmission electron microscope (TEM) image of a cross-section of a capacitor, according to at least one embodiment.

Referring to FIG. 9, it is determined that the capacitor of Embodiment 1 includes Ga, Al, and Zr in a direction from an upper electrode to a lower electrode. In particular, it is determined that Al and Ga are present on a same layer.

Through FIGS. 8B to 9, it is determined that the capacitor of Embodiment 1 includes an interface layer that simultaneously includes Al and Ga.

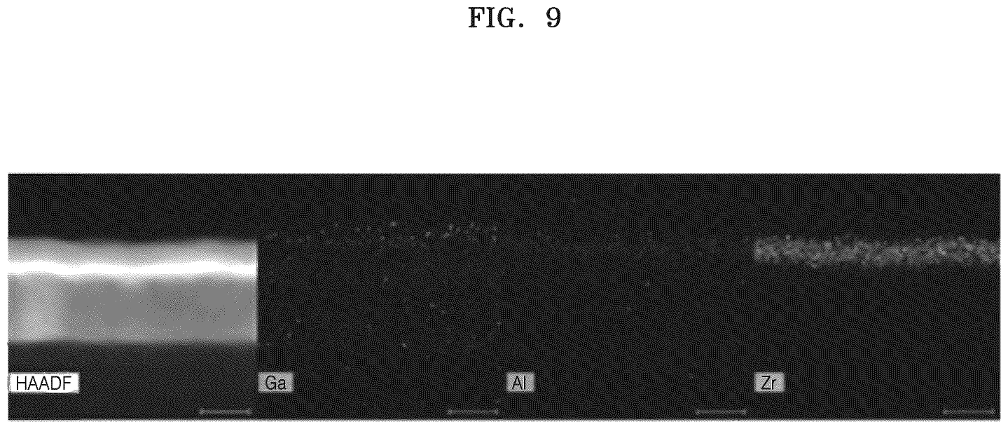

FIG. 10 illustrates an X-ray diffraction (XRD) spectrum showing crystallization of a capacitor, according to at least one embodiment.

Referring to FIG. 10, the capacitor of Embodiment 1 displays an XRD peak similar to the capacitor of Comparative Example 1, and accordingly, it is determined that the capacitor of Embodiment 1 has an interface layer having a tetragonal phase like the capacitor of Comparative Example 1. In other words, it is determined that the capacitor of Embodiment 1 in which an aluminum gallium oxide is applied to an interface layer displays high crystallization like the capacitor of Comparative Example 1 in which an aluminum oxide is applied to an interface layer.

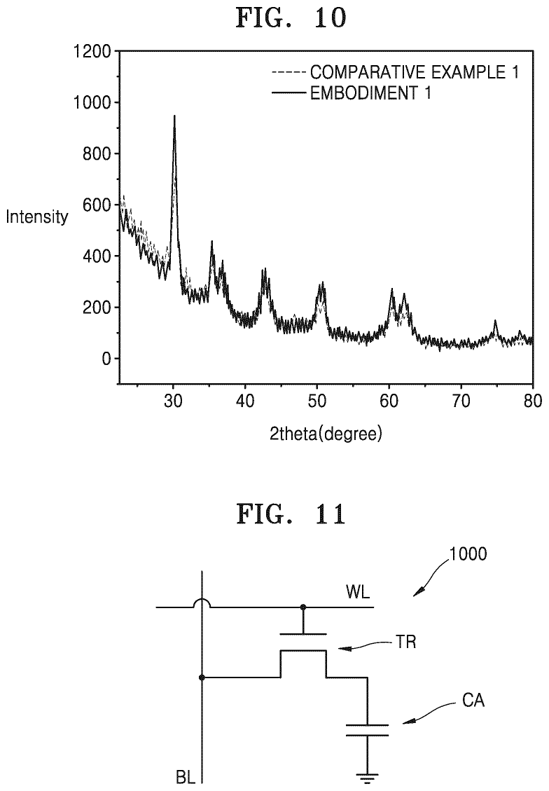

FIG. 11 is a circuit diagram for describing a schematic circuit configuration a semiconductor device 1000 employing a capacitor CA according to some embodiments.

The circuit diagram of the semiconductor device 1000 is related to one cell of a dynamic random access memory (DRAM) device, and includes one transistor TR, one capacitor CA, a word line WL, and a bit line BL. The capacitor CA may be the capacitor 100, 101, or 102 described with reference to FIG. 1, 4, or 5, which have been described above, and thus details thereof are not provided again.

A method of writing data on DRAM is as below. After applying a gate voltage (high) that turns the transistor TR to an “ON” state to a gate electrode through the word line WL, VDD (high) or 0 (low) that is a data voltage value to be input to the bit line BL is applied. When a high voltage is applied to the word line WL and the bit line BL, the capacitor CA is charged and data “1” is recorded, and when a high voltage is applied to the word line WL and a low voltage is applied to the bit line BL, the capacitor CA is discharged and data “0” is recorded.

When data is to be read, a high voltage is applied to the word line WL and then a voltage of VDD/2 is applied to the bit line BL to turn the transistor TR on. When data of DRAM is “1”, i.e., when a voltage of the capacitor CA is VDD, charges in the capacitor CA gradually move towards the bit line BL and thus, a voltage of the bit line BL increases slightly higher than VDD/2. On the other hand, when data of the capacitor CA is “0”, charges in the bit line BL move towards the capacitor CA and thus, the voltage of the bit line BL decreases slightly less than VDD/2. A sense amplifier detects a potential difference of the bit line BL generated as such and amplifies the same to determine whether the data is “0” or “1”.

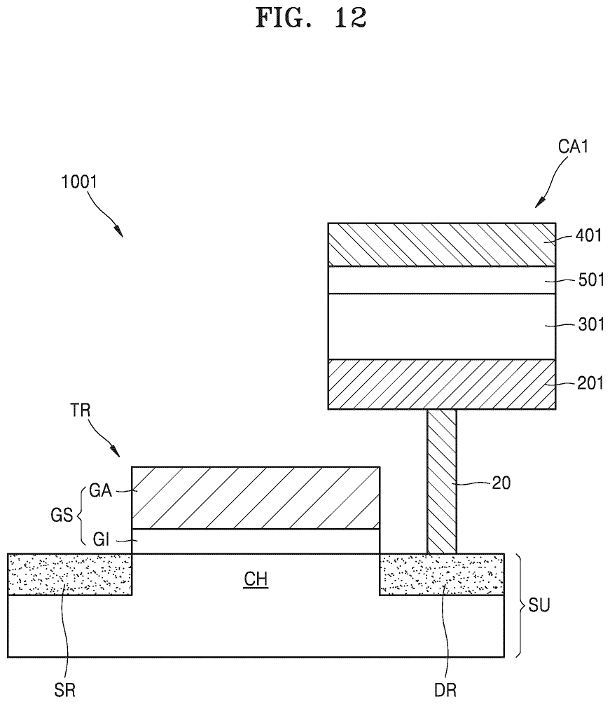

FIG. 12 is a diagram showing a semiconductor device 1001 according to at least one embodiment.

Referring to FIG. 12, in the semiconductor device 1001, a capacitor CA1 and the transistor TR may be electrically connected to each other by a contact 20. The capacitor CA1 includes a first electrode 201, a second electrode 401, a dielectric layer 301 arranged between the first electrode 201 and the second electrode 401, and an interface layer 501 arranged between the dielectric layer 301 and the second electrode 401. The capacitor CA1 may be the capacitor 100, 101, or 102 described with reference to FIG. 1, 4, or 5, which have been described above, and thus details thereof are not provided again.

The transistor TR may be a field effect transistor. The transistor TR may include a semiconductor substrate SU including a source region SR, a drain region DR, and a channel region CH, and a gate stack GS disposed on the semiconductor substrate SU to face the channel region CH and including a gate insulating layer GI and a gate electrode GA.

The channel region CH is a region between the source region SR and the drain region DR, and may be electrically connected to the source region SR and the drain region DR. The source region SR may be electrically connected to or in contact with one end portion of the channel region CH, and the drain region DR may be electrically connected to or in contact with another end portion of the channel region CH. The channel region CH may be defined as a substrate region between the source region SR and the drain region DR in the semiconductor substrate SU.

The semiconductor substrate SU may include a semiconductor material. The semiconductor substrate SU may include, for example, a semiconductor material, such as silicon (Si), germanium (Ge), SiGe, silicon carbide (SiC), gallium arsenide (GaAs), indium arsenide (InAs), or indium phosphide (InP). Also, the semiconductor substrate SU may include a silicon-on-insulator (SOI) substrate.

The source region SR, the drain region DR, and the channel region CH may be independently formed by injecting impurities into different regions of the semiconductor substrate SU. In this case, the source region SR, the channel region CH, and the drain region DR may include a substrate material as a base material. The source region SR and the drain region DR may be formed by a conductive material. In this case, the source region SR and the drain region DR may include, for example, a metal, a metal compound, or a conductive polymer.

Unlike illustrated, the channel region CH may include a separate material layer (e.g., a semiconductor thin film). In these cases, the channel region CH may include, for example, one or more of Si, Ge, SiGe, a group III-V semiconductor, an oxide semiconductor, a nitride semiconductor, an oxynitride semiconductor, a two-dimensional (2D) material), a quantum dot, an organic semiconductor, and/or the like. The oxide semiconductor may include, for example, InGaZnO. The 2D material may include, for example, transition metal dichalcogenide (TMD) or graphene. The quantum dot may include, for example, a colloidal quantum dot (QD) or nanocrystal.

The gate electrode GA may face the channel region CH while spaced apart from the semiconductor substrate SU above the semiconductor substrate SU. The gate electrode GA may include at least one of a metal, a metal nitride, a metal carbide, and polysilicon. The metal may include, for example, at least one of Al, W, Mo, Ti, and Ta. The metal nitride may include, for example, one or more of TiN film and TaN film. The metal carbide may include, for example, one or more of an Al and Si-doped (or contained) metal carbide. The metal carbide may include, for example, TiAlC, TaAlC, TiSiC, or TaSiC.

The gate electrode GA may have single-layer structure or a structure in which a plurality of materials are stacked on each other. The gate electrode GA may have, for example, a stack structure of metal nitride layer/metal layer, such as TiN/Al, or a stack structure of metal nitride/metal carbide layer/metal layer, such as TiN/TiAlC/W. The above-mentioned materials used for the gate electrode GA are only examples and the gate electrode GA is not limited thereto.

The gate insulating layer GI may be further arranged between the semiconductor substrate SU and the gate electrode GA. The gate insulating layer GI may include a paraelectric material or a high-k dielectric material. The gate insulating layer GI may have, for example, a dielectric constant from 20 to 70.

The gate insulating layer GI may include, for example, silicon oxide, silicon nitride, aluminum oxide, hafnium oxide, zirconium oxide, and/or may include a 2D insulator, such as hexagonal boron nitride (h-BN). The gate insulating layer GI may include, for example, silicon oxide (SiO₂), silicon nitride (SiNₓ), and/or the like, and may include hafnium oxide (HfO₂), hafnium silicon oxide (HfSiO₄), lanthanum oxide (La₂O₃), lanthanum aluminum oxide (LaAlO₃), zirconium oxide (ZrO₂), hafnium zirconium oxide (HfZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), red scandium tantalum oxide (PbSc_{0.5}Ta_{0.5}O₃), and/or red zinc niobate (PbZnNbO₃). The gate insulating layer GI may include, for example, a metal oxynitride, such as aluminum oxynitride (AlON), zirconium oxynitride (ZrON), hafnium oxynitride (HfON), lanthanum oxynitride (LaON), and/or yttrium oxynitride (YON), silicate such as ZrSiON, HfSiON, YSiON, or LaSiON, and/or aluminate, such as ZrAlON and/or HfAlON. The gate insulating layer GI may include, for example, a dielectric layer of a capacitor described above. The gate insulating layer GI may configure a gate stack, together with the gate electrode GA.

One of the first electrode 201 and the second electrode 401 of the capacitor CA1 may be electrically connected to one of the source region SR and the drain region DR of the transistor TR, e.g., by the contact 20. The contact 20 may include a suitable conductive material, for example, tungsten, copper, aluminum, or polysilicon.

Arrangements of the capacitor CA1 and transistor TR may be variously modified. For example, the capacitor CA1 may be arranged on the semiconductor substrate SU or embedded in the semiconductor substrate SU.

In FIG. 12, the semiconductor device 1001 includes one capacitor CA1 and one transistor TR, but this is only an example, and the semiconductor device 1001 may include a plurality of capacitors and a plurality of transistors.

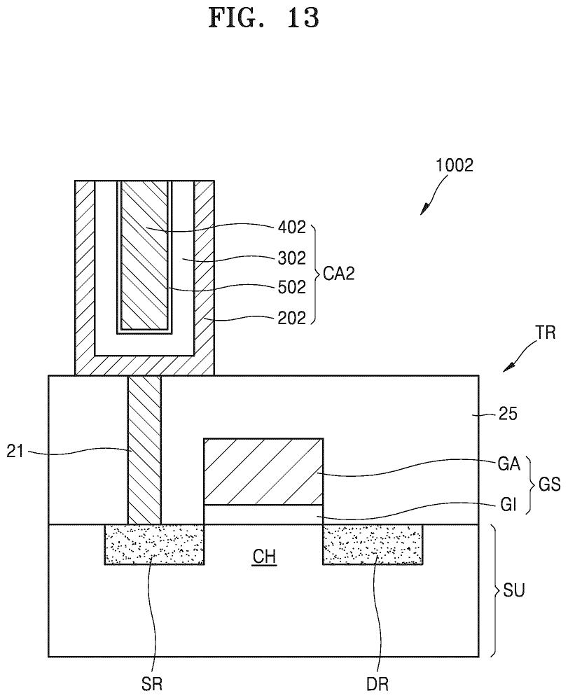

FIG. 13 is a diagram showing a semiconductor device 1002 according to at least one embodiment.

Referring to FIG. 13, in the semiconductor device 1002, a capacitor CA2 and the transistor TR may be electrically connected to each other by a contact 21.

The transistor TR may include the semiconductor substrate SU including the source region SR, the drain region DR, and the channel region CH located between the source region SR and the drain region DR, and the gate stack GS including the gate electrode GA and the gate insulating layer GI facing the channel region CH on the semiconductor substrate SU.

An interlayer insulating layer 25 may be provided to cover the gate stack GS on the semiconductor substrate SU. The interlayer insulating layer 25 may include an insulating material. The interlayer insulating layer 25 may include, for example, a silicon oxide (e.g., SiO₂), an aluminum oxide (e.g., Al₂O₃), or a high-k dielectric material (e.g., HfO₂). The contact 21 electrically connects the transistor TR and the capacitor CA1 to each other by penetrating the interlayer insulating layer 25.

The capacitor CA2 may include a first electrode 202, a second electrode 402, a dielectric layer 302 arranged between the first electrode 202 and the second electrode 402, and an interface layer 502 arranged between the dielectric layer 302 and the second electrode 402. The first electrode 202 and the second electrode 402 may be presented in a shape for increasing a contact area with the dielectric layer 302 as large as possible, and a material of the capacitor CA2 may be substantially the same as that of the capacitor 100, 101, or 102 described with reference to FIG. 1, 4, or 5.

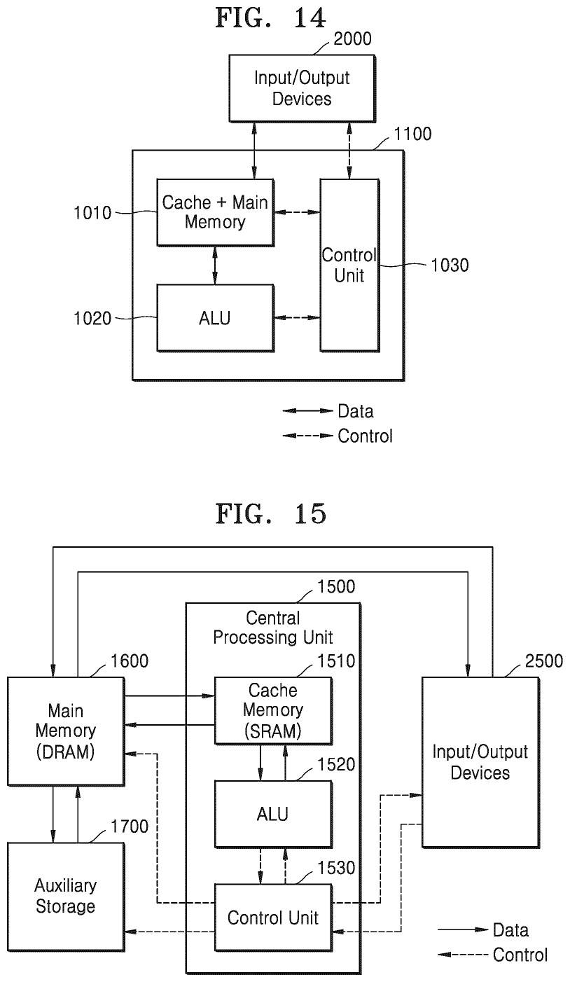

FIGS. 14 and 15 are conceptual diagrams schematically showing device architectures applicable to a semiconductor device, according to some embodiments.

Referring to FIG. 14, a device architecture 1100 may include a memory unit 1010, an arithmetic logic unit (ALU) 1020, and a control unit 1030. The memory unit 1010, the ALU 1020, and the control unit 1030 may be electrically connected to each other. The device architecture 1100 may be implemented as, for example, one chip including the memory unit 1010, the ALU 1020, and the control unit 1030.

The memory unit 1010, the ALU 1020, and the control unit 1030 may be connected to each other through a metal line on-chip and directly communicate with each other. The memory unit 1010, the ALU 1020, and the control unit 1030 may configure on a chip by being monolithically integrated on one substrate. The device architecture (chip) 1100 may be connected to input/output devices 2000. The memory unit 1010 may include both a main memory and a cache memory. Such a device architecture (chip) 1100 may be an on-chip memory processing unit. The memory unit 1010 may include the above-described capacitor and a semiconductor device using the same. The ALU 1020 or the control unit 1030 may also include the above-described capacitor.

Referring to FIG. 15, a cache memory 1510, an ALU 1520, and a control unit 1530 may configure a central processing unit (CPU) 1500, and the cache memory 1510 may be static random-access memory (SRAM). A main memory 1600 and an auxiliary storage 1700 may be provided separately from the CPU 1500, and input/output devices 2500 may be provided. The main memory 1600 may be, for example, dynamic random-access memory (DRAM), and may include the capacitor 100, 101, or 102 described with reference to FIG. 1, 4, or 5. For example, in at least one embodiment, the cache memory unit 1510, auxiliary memory 1700, and/or the main memory 1600, may include a plurality of the semiconductor device arranged in an array and configured to store data using a plurality of the capacitor 100, 101, or 102.

The input/output device (and/or devices) 2000 and 2500 may include, for example, an input device (such as a microphone, touch pad, electronic mouse, keyboard, keypad, camera, etc.) and/or an output device (such as a speaker, display, haptic system, etc.). According to at least some example embodiments, the input/output devices 2000 and 2500 may be provided individually and/or in combination (e.g., a touch screen display).

In some cases, a device architecture may be implemented in the form in which computing unit devices and memory unit devices are adjacent to each other in one chip, without distinction of sub-units.

According to some embodiments, a capacitor includes an interface layer, the interface layer includes a first element, a second element, and a third element, the first element includes Al, the second element includes Ga, and the third element includes O, and thus the capacitor may have high capacitance and low leakage current characteristics.

According to some embodiments, a semiconductor device including such a capacitor may be easily highly integrated and thus may contribute to miniaturization of an electronic device.

A capacitor of the disclosure and a semiconductor device including the same include an interface layer including aluminum gallium oxide, and thus low leakage current density and high capacitance may be simultaneously exhibited. It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode;
a second electrode spaced apart from the first electrode;
a dielectric layer configured to electrically insulate the first electrode from the second electrode; and
an interface layer between the second electrode and the dielectric layer,
wherein the interface layer comprises a first element, a second element, and a third element,
the first element comprises aluminum (Al),
the second element comprises gallium (Ga), and
the third element comprises oxygen (O).

2. The capacitor of claim 1, wherein
the interface layer comprises a plurality of layers, and
the plurality of layers comprise at least one first layer comprising an aluminum oxide and at least one second layer comprising a gallium oxide.

3. The capacitor of claim 1, wherein the interface layer is amorphous.

4. The capacitor of claim 1, wherein
the interface layer is in direct contact with the second electrode, and
the interface layer is in direct contact with the dielectric layer.

5. The capacitor of claim 1, wherein the first electrode comprises at least one of:
titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb);
an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, or an oxide of Nb;
a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb; or
a combination thereof.

6. The capacitor of claim 5, wherein
the interface layer is a first interface layer and
the capacitor further comprises a second interface layer between the dielectric layer and the first electrode.

7. The capacitor of claim 6, wherein the second interface layer comprises an oxide of a material included in the first electrode.

8. The capacitor of claim 5, wherein the second electrode comprises a same material as the first electrode.

9. The capacitor of claim 1, wherein the dielectric layer comprises at least one of zirconium oxide (ZrO₂), hafnium oxide (HfO₂), titanium oxide (TiO₂), aluminum oxide (Al₂O₃), or a combination thereof.

10. The capacitor of claim 1, wherein the dielectric layer comprises an oxide having a perovskite type crystal structure.

11. The capacitor of claim 10, wherein the dielectric layer comprises at least one of strontium (Sr), barium (Ba), titanium (Ti), hafnium (Hf), yttrium (Y), or a combination thereof and oxygen (O).

12. The capacitor of claim 1, wherein a thickness of the interface layer is 15 Å or less.

13. The capacitor of claim 1, wherein a thickness of the dielectric layer is 100 Å or less.

14. A semiconductor device comprising:
a transistor comprising a semiconductor substrate, the semiconductor substrate comprising a source region, a drain region, a channel region between the source region and the drain region, and a gate stack over the channel region; and
a capacitor electrically connected to the transistor,
wherein the capacitor comprises
a first electrode,
a second electrode spaced apart from the first electrode,
a dielectric layer configured to electrically insulate the first electrode from the second electrode, and
an interface layer between the second electrode and the dielectric layer, and
wherein the interface layer comprises a first element, a second element, and a third element,
the first element comprises aluminum (Al),
the second element comprises gallium (Ga), and
the third element comprises oxygen (O).

15. The semiconductor device of claim 14, wherein
the interface layer comprises a plurality of layers, and
the plurality of layers comprise at least one first layer comprising an aluminum oxide and at least one second layer comprising a gallium oxide.

16. The semiconductor device of claim 14, wherein the interface layer is amorphous.

17. The semiconductor device of claim 14, wherein
the interface layer is in direct contact with the second electrode, and
the interface layer is in direct contact with the dielectric layer.

18. The semiconductor device of claim 14, wherein the first electrode comprises at least one of
titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb);
an oxide of Ti, an oxide of Ni, an oxide of Al, an oxide of Ta, an oxide of W, an oxide of Pt, an oxide of Pd, an oxide of Au, an oxide of Ir, an oxide of Rh, an oxide of Mo, an oxide of V, or an oxide of Nb;
a nitride of Ti, a nitride of Ni, a nitride of Al, a nitride of Ta, a nitride of W, a nitride of Pt, a nitride of Pd, a nitride of Au, a nitride of Ir, a nitride of Rh, a nitride of Mo, a nitride of V, or a nitride of Nb; or
a combination thereof.

19. The semiconductor device of claim 18, wherein
the interface layer is a first interface layer, and
the capacitor further comprises a second interface layer arranged between the dielectric layer and the first electrode.

20. The semiconductor device of claim 14, wherein the dielectric layer comprises a zirconium oxide (ZrO₂), a hafnium oxide (HfO₂), a titanium oxide (TiO₂), an aluminum oxide (Al₂O₃), or a combination thereof.
